(19) United States
(12) Patent Application Publication
(10) Pub. No.: US 2025/0380356 A1
(43) Pub. Date: Dec. 11, 2025

(54) SERVICE LOOP MANAGEMENT

(71) Applicant: Apple Inc., Cupertino, CA (US)

(72) Inventors: Jamie N. Forslin, San Jose, CA (US); Thomas A. Boehler, San Jose, CA (US); Jonathan M. Parson, Cupertino, CA (US); Russell K. Williams, San Francisco, CA (US); Danielle Loi, Cupertino, CA (US); Dominic Pitera, San Francisco, CA (US)

(21) Appl. No.: 19/217,904

(22) Filed: May 23, 2025

Related U.S. Application Data
(60) Provisional application No. 63/658,339, filed on Jun. 10, 2024.

(51) Int. Cl. H05K 1/02; H05K 1/09; H05K 1/14

(52) U.S. Cl. CPC H05K 1/0281; H05K 1/09; H05K 1/147; H05K 2201/10409

(57) ABSTRACT

Aspects of the present disclosure involve a cowling configured to be attached to a flexible circuit board. In general, a device includes a flexible circuit board and a cowling. A first end of the cowling is configured to be attached to a first surface of the flexible circuit board to maintain a portion of the flexible circuit board in a compressed state under the cowling. The first end of the cowling is configured to be detached from the first surface of the flexible circuit board to enable the portion of the flexible circuit board to transition out of the compressed state and into a decompressed state.

### PRIORITY

The disclosure claims the benefit under 35 U.S.C. § 119 (e) of U.S. Provisional Patent Application No. 63/658,339 entitled “Service Loop Management”, filed on Jun. 10, 2024, which is incorporated herein by reference in its entirety.

### TECHNICAL FIELD

This disclosure relates generally to flexible circuit boards, and more specifically to a cowling configured to be attached to a flexible circuit board.

### BACKGROUND

Many devices, such as portable electronic devices, include components that need to occasionally be removed and/or replaced. However, ensuring that such components can be removed and/or replaced without damaging other components of the device is a continual challenge. It is with these and other issues in mind that various aspects of the present disclosure were developed.

### SUMMARY

In one aspect, the disclosure is directed to a device that includes a flexible circuit board and a cowling. In general, a first end of the cowling is configured to be attached to a first surface of the flexible circuit board to maintain a portion of the flexible circuit board in a compressed state under the cowling. The first end of the cowling is configured to be detached from the first surface of the flexible circuit board to enable the portion of the flexible circuit board to transition out of the compressed state and into a decompressed state.

In a further aspect, the disclosure is directed to a cowling configured to be attached to a flexible circuit board. The cowling can include a first end configured to be attached to a first surface of a flexible circuit board to maintain a portion of the flexible circuit board of the flexible circuit board in a compressed state under the cowling. The first end of the cowling can be configured to detach from the first surface of the flexible circuit board to enable the portion of the flexible circuit board to transition out of the compressed state and into a decompressed state.

### BRIEF DESCRIPTION OF THE DRAWINGS

Although the following figures and description illustrate specific embodiments and examples, the skilled artisan will appreciate that various changes and modifications may be made without departing from the spirit and scope of the disclosure.

FIG. 1A is a side view of a cowling attached to a flexible circuit board to contain a portion of the flexible circuit board in a compressed state, according to an illustrative embodiment;

FIG. 1B is a side view of a cowling detached from a flexible circuit board to stretch a portion of the flexible circuit board into a decompressed state, according to an illustrative embodiment;

FIG. 2 is a side view of a cowling attached to a flexible circuit board to contain a portion of the flexible circuit board in a compressed state, according to an illustrative embodiment;

FIG. 3A is an isometric view of a cowling attached to a flexible circuit board to contain a portion of the flexible circuit board in a compressed state, according to an illustrative embodiment;

FIG. 3B is an isometric view of a cowling attached to a flexible circuit board to contain a portion of the flexible circuit board in a compressed state, according to an illustrative embodiment;

FIG. 3C is an isometric view of a cowling attached to a flexible circuit board to contain a portion of the flexible circuit board in a compressed state, according to an illustrative embodiment;

FIG. 4 is a side view of a cowling attached to a flexible circuit board to contain a portion of the flexible circuit board in a compressed state, according to an illustrative embodiment;

FIG. 5 illustrates an example method for removing components from a device, according to an illustrative embodiment; and

FIG. 6 is a portable electronic device, according to an illustrative embodiment.

### DETAILED DESCRIPTION

The following description is presented to allow any person skilled in the art to make and use the embodiments, and is provided in the context of a particular application. Various modifications to the disclosed embodiments will be readily apparent to those skilled in the art, and the general principles defined herein may be applied to other embodiments and applications without departing from the spirit and scope of the present disclosure. It should be understood that the following descriptions are not intended to limit the embodiments to one preferred embodiment. To the contrary, it is intended to cover alternatives, modifications, and equivalents as can be included within the spirit and scope of the described embodiments as defined by the appended claims. Thus, the disclosure is not limited to the embodiments shown, but is to be accorded the widest scope consistent with the principles and features disclosed herein.

When introducing elements of various embodiments of the present disclosure, the articles “a,” “an,” and “the” are intended to mean that there are one or more of the elements. The terms “comprising,” “including,” and “having” are intended to be inclusive and mean that there may be additional elements other than the listed elements. Additionally, it should be understood that references to “one embodiment” or “an embodiment” of the present disclosure are not intended to be interpreted as excluding the existence of additional embodiments that also incorporate the recited features. Furthermore, the particular features, structures, or characteristics may be combined in any suitable manner in one or more embodiments. Use of the terms “approximately,” “near,” “about,” “close to,” and/or “substantially” should be understood to mean including close to a target (e.g., design, value, amount), such as within a margin of any suitable or contemplatable error (e.g., within 0.1% of a target, within 1% of a target, within 5% of a target, within 10% of a target, within 25% of a target, and so on). Moreover, it should be understood that any exact values, numbers, measurements, and so on, provided herein, are contemplated to include approximations (e.g., within a margin of suitable or contemplatable error) of the exact values, numbers, measurements, and so on).

As noted above, aspects of the present disclosure involve a device that includes a flexible circuit board and a cowling. In general, a first end of the cowling is configured to be attached to a first surface of the flexible circuit board to maintain a portion of the flexible circuit board in a compressed state under the cowling. The first end of the cowling is configured to be detached from the first surface of the flexible circuit board to enable the portion of the flexible circuit board out of the compressed state and into a decompressed state.

Through the use of this particular cowling, several advantages may be obtained over conventional devices. For example, a conventional device can include one or more components, such as a main logic board (MLB), that occasionally need to be removed from the device, such as for repair or replacement. It can be difficult to remove these components without also removing one or more of the battery cells from the device. For example, a device can include an MLB that is positioned in between two battery cells. A flexible circuit board can be routed over the MLB. As such, removing the MLB can necessitate a removal of at least one of the two battery cells. However, removing a battery cell from the device can ruin the adhesive used to adhere the battery cell to the system. If the adhesive is ruined, the battery cell cannot be reused.

The improved device described herein includes a cowling that can be attached to a flexible circuit board, such as a flexible circuit board routed over an MLB. The cowling can be attached to the flexible circuit board to maintain an excess portion of the flexible circuit board compressed in an state under the cowling. The cowling can be detached from flexible circuit board to enable the excess portion of the flexible circuit board to transition out of or stretch out of the compressed state and into a decompressed state. Enabling the excess portion of the flexible circuit board to transition or stretch out of the compressed state and into the decompressed state can generate a space between the cowling and the flexible circuit board. The space can provide clearance to remove one or more components, such as the MLB, from the device without removing other components, such as one or more battery cells, from the device.

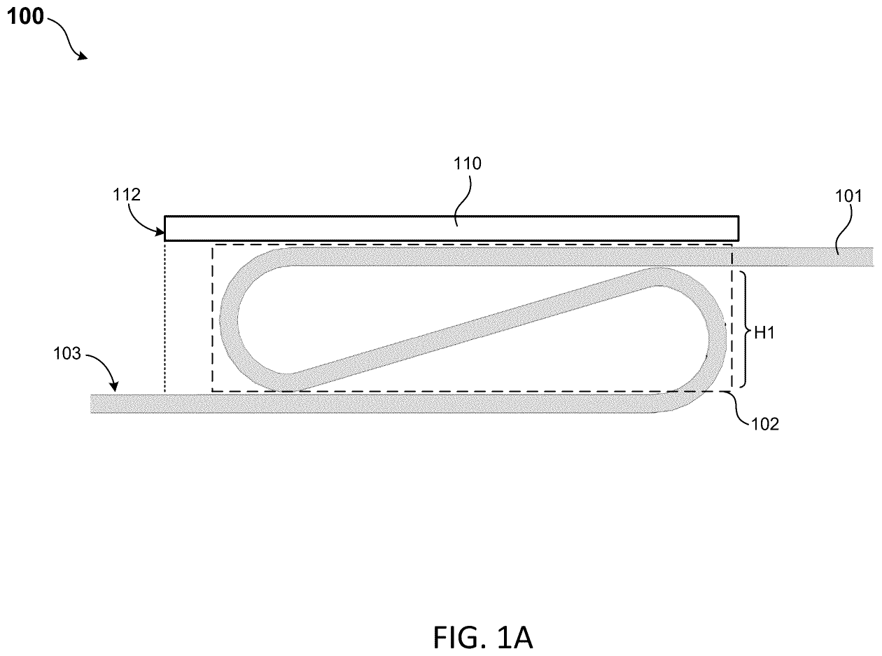

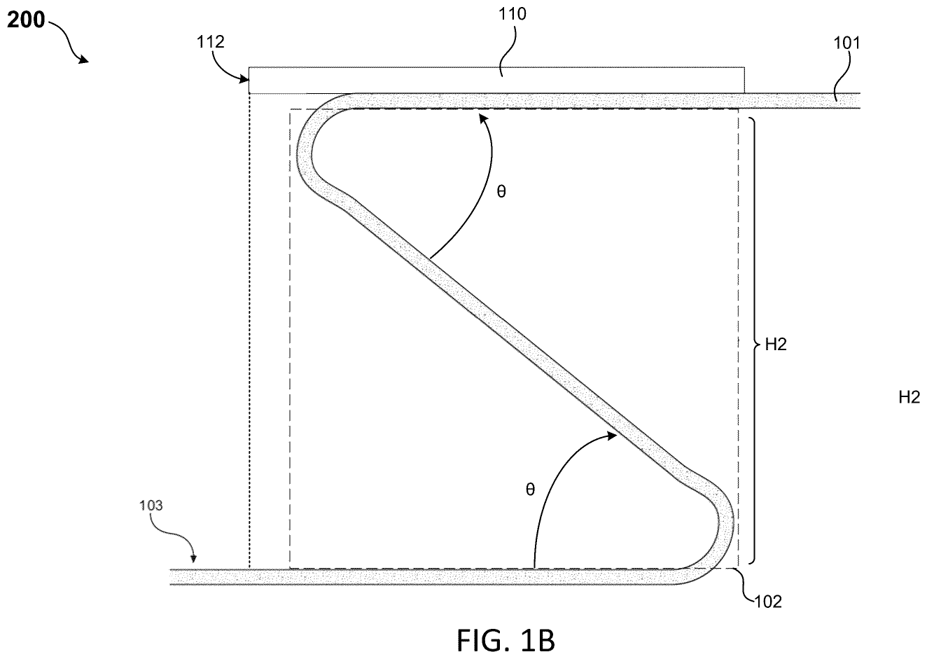

FIG. 1A is a side view 100 of a cowling 110 attached to a flexible circuit board 101. The flexible circuit board 101 can include an excess portion 102, such as a service loop. The flexible circuit board 101 can be a material comprising copper, such as hyper-annealed copper. The flexible circuit board 101 can include two layers of copper. The flexible circuit board 101 can have a thickness of 125 micrometers, 150 micrometers, 175 micrometers, 200 micrometers, or any other thickness. The flexible circuit board 101 can be installed in a device and routed over one or more components of the device, such as an MLB of the device.

The cowling 110 can be a material comprising stainless steel. The cowling 110 can have a thickness of 125 micrometers, 150 micrometers, 175 micrometers, 200 micrometers, or any other thickness. The cowling 110 can have a width of 10 millimeters, 12 millimeters, 14 millimeters, 16 millimeters, or any other width. The cowling 110 can have a length of 5 millimeters, 6 millimeters, 7 millimeters, 8 millimeters, or any other length.

The cowling 110 can be attached to the flexible circuit board 101 to maintain or contain the excess portion 102 of the flexible circuit board 101 in a compressed state under the cowling 110. If the cowling 110 is attached to the flexible circuit board 101, the cowling 110 can apply a compression force on the excess portion 102 of the flexible circuit board 101 to maintain the excess portion 102 of the flexible circuit board 101 in the compressed state under the cowling 110. The compression force can be great enough to maintain the excess portion 102 of the flexible circuit board 101 in the compressed state under the cowling 110 without damaging the excess portion 102 of the flexible circuit board 101.

In embodiments, the excess portion 102 of the flexible circuit board 101 can bend back over itself to form the compressed state. The compressed state can form two rounded or arced angles.

In embodiments, the cowling 110 can include a first end 112. The first end 112 of the cowling 110 can be attached to a first surface 103 of the flexible circuit board 101 to maintain the excess portion 102 of the flexible circuit board 101 in the compressed state under the cowling 110. The first end 112 of the cowling 110 can be attached to a first surface 103 of the flexible circuit board 101 to maintain the excess portion 102 of the flexible circuit board 101 in the compressed state between the cowling 110 and the first surface 103 of the flexible circuit board 101. The first surface 103 can be a top surface of the flexible circuit board 101.

In embodiments, a height H1 of the excess portion 102 of the flexible circuit board 101 maintained in the compressed state can be, for example, 2 millimeters, 2.5 millimeters, 3 millimeters, or any other height.

In embodiments, the cowling 110 can be detached from the flexible circuit board 101. Detaching the cowling 110 from the flexible circuit board 101 can remove the compression force applied by the cowling 110 on the excess portion 102 of the flexible circuit board 101. The cowling 110 can be detached from the flexible circuit board 101 to enable the excess portion 102 of the flexible circuit board 101 to transition or stretch out of the compressed state and into a decompressed state.

FIG. 1B is a side view 200 of the cowling 110 detached from the flexible circuit board 101. The first end 112 of the cowling 110 can be detached from the first surface 103 of the flexible circuit board 101 to enable the excess portion 102 of the flexible circuit board 101 to transition or stretch out of the compressed state and into a decompressed state. The decompressed state can form two angles θ. θ can be equal to, or substantially equal to, 45 degrees.

In embodiments, a height H2 of the excess portion 102 of the flexible circuit board 101 in the decompressed state can be greater than H1. The height H2 can be up to 2.5 times greater than the height H1. The height H2 can be, for example, 4 millimeters, 5 millimeters, 6 millimeters, or any other height that is greater than H1.

In embodiments, enabling the excess portion 102 of the flexible circuit board 101 to transition or stretch out of the compressed state and into the decompressed state can generate a space between the cowling 110 and the flexible circuit board 101, such as between the cowling 110 and the first surface 103 of the flexible circuit board 101. The space can provide clearance to remove and/or install one or more components, such as an MLB, from a device without removing other components, such as one or more battery cells, from the device.

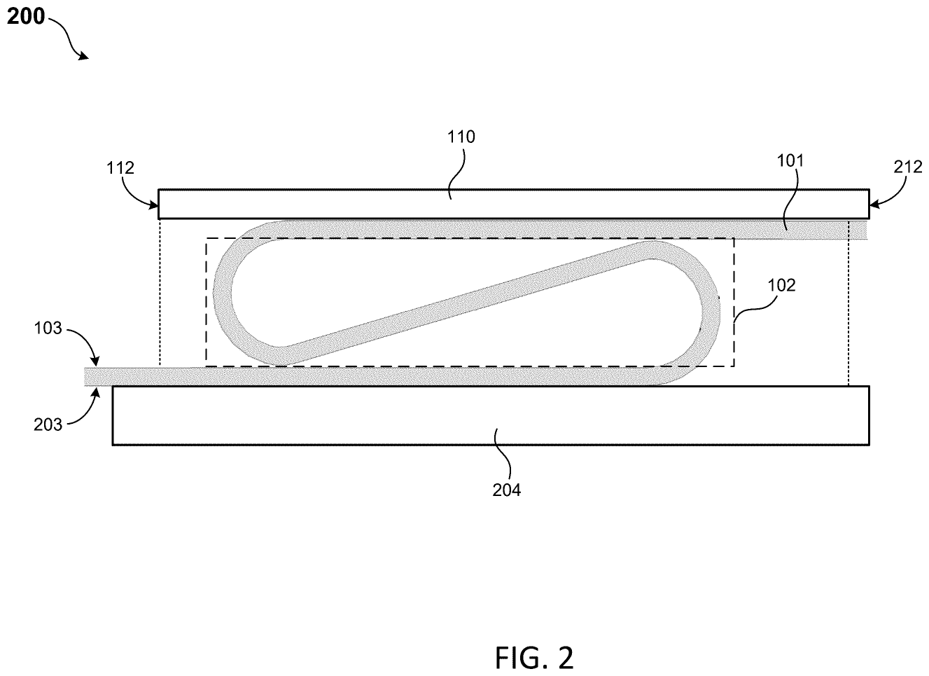

In embodiments, a second end of the cowling 110 can be attached to or secured to one or more components of the device. FIG. 2 is a side view 200 of the cowling 110 attached to the flexible circuit board 101 and a device component 204 to maintain the excess portion 102 of the flexible circuit board 101 in the compressed state. The device component 204 can be positioned below a second surface 203 of the flexible circuit board 101. For example, the flexible circuit board 101 can be routed over the device component 204. The device component 204 can be an MLB, or any other device component.

The cowling 110 can include a second end 212. The second end 212 of the cowling 110 can be attached to the device component 204 to help maintain the excess portion 102 of the flexible circuit board 101 in the compressed state. The second end 212 of the cowling 110 can be detached from the device component 204 to enable the excess portion 102 of the flexible circuit board 101 to transition or stretch out of the compressed state and into the decompressed state.

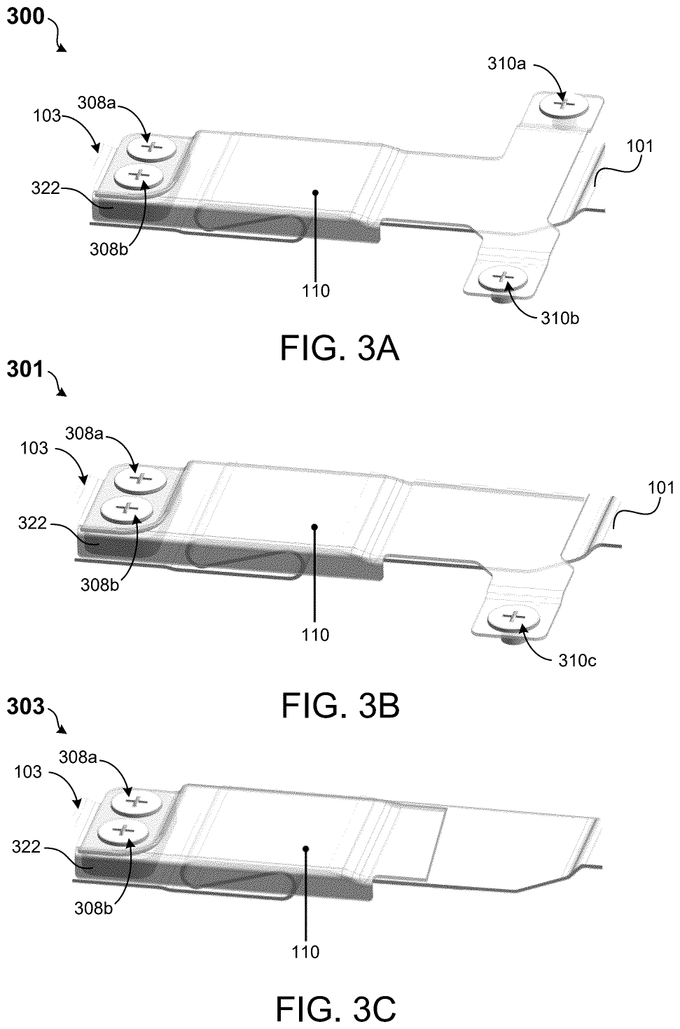

The cowling 110 can have a T-shape. FIG. 3A is an isometric view 300 of the cowling 110 having a T-shape attached to the flexible circuit board 101 to maintain the excess portion 102 of the flexible circuit board 101 in the compressed state. At least one boss 322 can be attached to the first surface 103 of the flexible circuit board 101. The at least one boss 322 can be attached to the first surface 103 of the flexible circuit board 101 using an adhesive, for example. The first end 112 of the cowling 110 can be attached to the first surface 103 of the flexible circuit board 101 using the at least one boss 322. For example, the first end 112 of the cowling 110 can be screwed into or attached to the at least one boss 322 at one or more locations 308a-b.

The second end 212 of the cowling 110 can be attached to the device component 204 at at least two locations 310a-b to help maintain the excess portion 102 of the flexible circuit board 101 in the compressed state. For example, the second end 212 of the cowling 110 can be screwed into or adhered to the device component 204 at the two locations 310a-b.

The cowling 110 can have an L-shape. FIG. 3B is an isometric view 301 of the cowling 110 having an L-shape attached to the flexible circuit board 101 to maintain the excess portion 102 of the flexible circuit board 101 in the compressed state. The at least one boss 322 can be attached to the first surface 103 of the flexible circuit board 101. The at least one boss 322 can be attached to the first surface 103 of the flexible circuit board 101 using an adhesive, for example. The first end 112 of the cowling 110 can be attached to the first surface 103 of the flexible circuit board 101 using the at least one boss 322. For example, the first end 112 of the cowling 110 can be screwed into or attached to the at least one boss 322 at one or more locations 308a-b.

The second end 212 of the cowling 110 can be attached to the device component 204 at a single locations 310c to help maintain the excess portion 102 of the flexible circuit board 101 in the compressed state. For example, the second end 212 of the cowling 110 can be screwed into or adhered to the device component 204 at the single locations 310c.

The cowling 110 can have a rectangular shape. FIG. 3C is an isometric view 303 of the cowling 110 having a rectangular shape attached to the flexible circuit board 101 to maintain the excess portion 102 of the flexible circuit board 101 in the compressed state. The at least one boss 322 can be attached to the first surface 103 of the flexible circuit board 101. The at least one boss 322 can be attached to the first surface 103 of the flexible circuit board 101 using an adhesive, for example. The first end 112 of the cowling 110 can be attached to the first surface 103 of the flexible circuit board 101 using the at least one boss 322. For example, the first end 112 of the cowling 110 can be screwed into or attached to the at least one boss 322 at one or more locations 308a-b. The second end 212 of the cowling 110 can be detached from the flexible circuit board 101 and/or any device component. For example, the second end 212 of the cowling 110 may not be attached to, such as screwed into or adhered to, the flexible circuit board 101 and/or any device component.

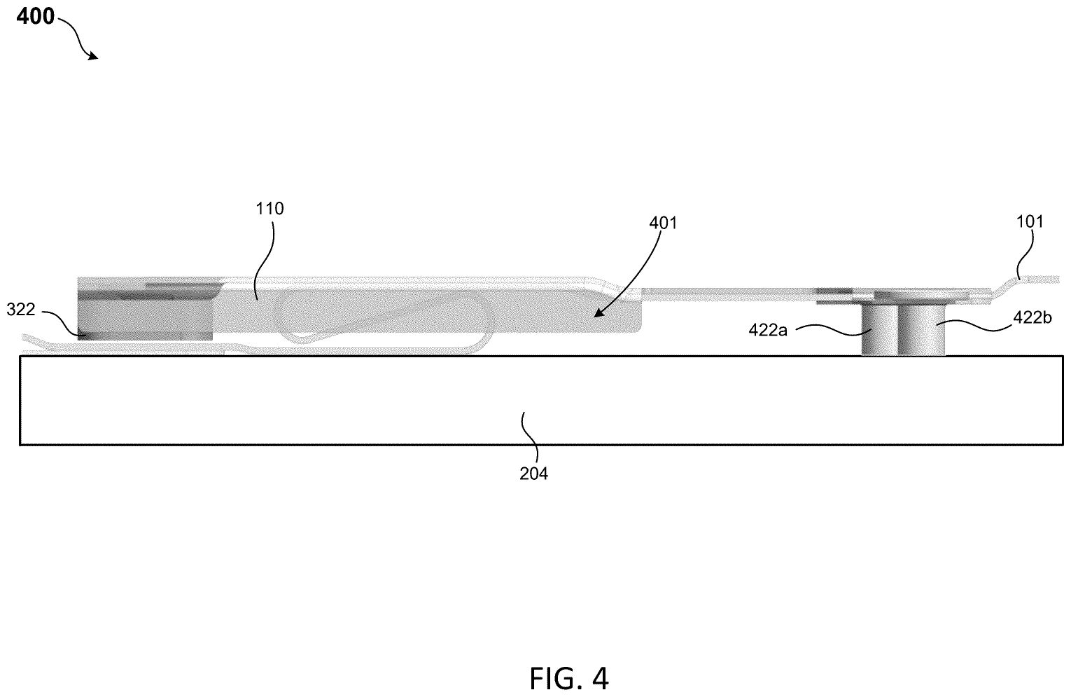

FIG. 4 is a side view 400 of the cowling 110 attached to the flexible circuit board 101 and the device component 204 to maintain the excess portion 102 of the flexible circuit board 101 in the compressed state.

The at least one boss 322 can be attached to the first surface 103 of the flexible circuit board 101. The at least one boss 322 can be attached to the first surface 103 of the flexible circuit board 101 using an adhesive, for example. The first end 112 of the cowling 110 can be attached to the first surface 103 of the flexible circuit board 101 using the at least one boss 322. For example, the first end 112 of the cowling 110 can be screwed into or attached to the at least one boss 322 at one or more locations 308a-b.

At least one additional boss 422a-b can be attached to the device component 204. The at least one additional boss 422a-b can be attached to a top surface of the device component 204. The at least one additional boss 422a-b can be attached to the device component 204 using an adhesive, for example. The second end 212 of the cowling 110 can be attached to the device component 204 using the at least one additional boss 422a-b. For example, the second end 212 of the cowling 110 can be screwed into or attached to the at least one additional boss 422a-b at one or more locations 308a-b.

In embodiments, the cowling 110 includes a side wall 401. The side wall 401 can extend in a perpendicular direction from a top surface of the cowling 110 towards the device component 204. The side wall 401 can protect the excess portion 102 of the flexible circuit board 101 from damage, such as damage caused by interacting with other device components.

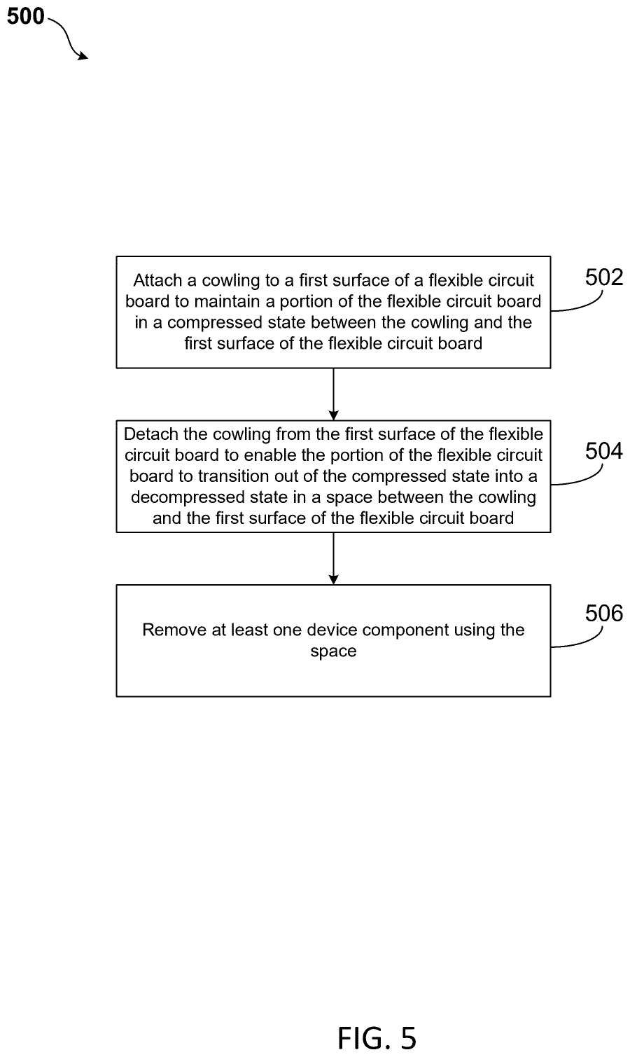

FIG. 5 illustrates an example method 500 for removing components from and/or installing components in a device in accordance with various aspects of the subject technology. It should be understood that, for any process discussed herein, there can be additional, fewer, or alternative steps performed in similar or alternative orders, or in parallel, within the scope of the various embodiments unless otherwise stated.

At operation 502, the cowling 110 is attached to the first surface 103 of the flexible circuit board 101. Attaching the cowling 110 to the first surface 103 of the flexible circuit board 101 can include attaching the first end 122 of the cowling 110 to the first surface 103 of the flexible circuit board 101. Attaching the cowling 110 to the first surface 103 of the flexible circuit board 101 can maintain the excess portion 102 of the flexible circuit board 101 in a compressed state under the cowling 110. For example, attaching the cowling 110 to the first surface 103 of the flexible circuit board 101 can maintain the excess portion 102 of the flexible circuit board 101 in a compressed state between the cowling 110 and the first surface 103 of the flexible circuit board 101.

In embodiments, attaching the cowling 110 to first surface 103 of the flexible circuit board 101 can cause the cowling 110 to apply a compression force on the excess portion 102 of the flexible circuit board 101, thereby maintaining the excess portion 102 of the flexible circuit board 101 in the compressed state under the cowling 110. The compression force can be great enough to maintain the excess portion 102 of the flexible circuit board 101 in the compressed state under the cowling 110 without damaging the excess portion 102 of the flexible circuit board 101.

In embodiments, at least one boss 322 is attached to the first surface 103 of the flexible circuit board 101. The first end 112 of the cowling 110 can be attached to the first surface 103 of the flexible circuit board using the at least one boss 322. For example, the first end 112 of the cowling 110 can be screwed into or attached to the at least one boss 322 at one or more locations 308a-b.

At operation 504, the cowling 110 is detached from the first surface 103 of the flexible circuit board 101. The cowling 110 can be detached from the first surface 103 of the flexible circuit board 101 to enable the excess portion 102 of the flexible circuit board 101 to transition or stretch out of the state. Transitioning the excess portion 102 of the flexible circuit board 101 out of the compressed state and into a decompressed state can generate a space between the cowling 110 and the first surface 103 of the flexible circuit board 101.

The space can provide clearance to remove and/or install one or more components, such as an MLB, from a device without removing other components, such as one or more battery cells, from the device. At operation 506, at least one device component is installed or removed using the space.

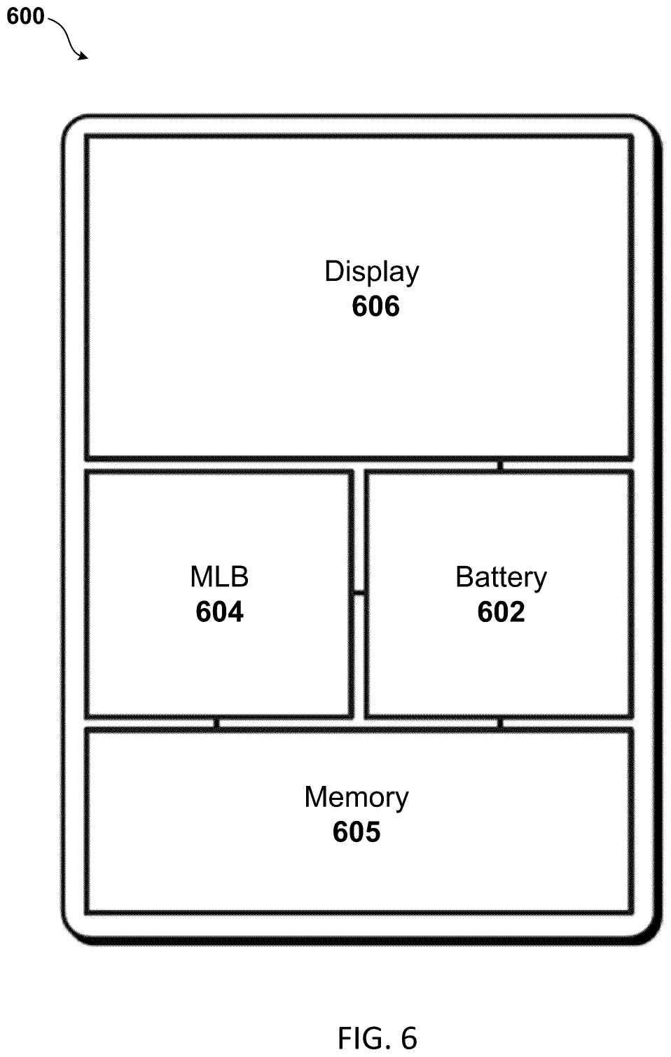

FIG. 6 illustrates a portable electronic device 600, in accordance with various aspects of the subject technology. The portable electronic device 600 includes a battery 602. The portable electronic device 600 includes a main logic board 604, a memory 605, and a display 4606, which are all powered by the battery 602. Portable electronic device 600 may correspond to a laptop computer, tablet computer, mobile phone, personal digital assistant (PDA), digital music player, watch, and wearable device, and/or other type of battery-powered electronic device.

The main logic board 604 can be the main circuit board of the portable electronic device 600. The main logic board 604 can include one or more of a central processing unit, a main system memory, and circuitry that controls the components of the portable electronic device 600 and/or other peripheral devices.

The battery 602 can include a single battery cell, or two or more battery cells. Each battery cell can include a battery stack and an enclosure enclosing the battery stack. The battery stack can include a plurality of layers comprising a cathode with an active coating, a separator, and an anode with an active coating. For example, the cathode can be an aluminum foil coated with a lithium compound (e.g., LiCoO₂, LiNCoMn, LiCoAl or LiMn2O4) and the anode can be a copper foil coated with carbon or graphite. The separator can include polyethylene (PE), polypropylene (PP), and/or a combination of PE and PP, such as PE/PP or PP/PE/PP.

The plurality of layers can be wound to form a jelly roll structure or can be stacked to form a stacked-cell structure. The plurality of layers may be enclosed within the enclosure and immersed in an electrolyte, which for example, can be a LiPF6-based electrolyte that can include Ethylene Carbonate (EC), Polypropylene Carbonate (PC), Ethyl Methyl Carbonate (EMC) or DiMethyl Carbonate (DMC). The electrolyte can also include additives such as Vinyl carbonate (VC) or Polyethylene Soltone (PS). The electrolyte can additionally be in the form of a solution or a gel.

The enclosure may comprise a plurality of faces (e.g., sides). For example, the enclosure may comprise a top face, a bottom face, and one or more side faces. However, it should be appreciated that the enclosure may be any size or shape and may include any number of faces and/or angles.

The flexible circuit board 101 can be routed over the main logic board 604. The battery 602 can include a first battery cell positioned on one side of the main logic board 604 and a second battery cell positioned on the other side of the main logic board 604. The cowling 110 can be attached to the flexible circuit board 101 to maintain the excess portion 102 of the flexible circuit board 101 in a compressed state under the cowling 110. If the cowling 110 is attached to the flexible circuit board 101, the cowling 110 can apply a compression force on the excess portion 102 of the flexible circuit board 101 to maintain the excess portion 102 of the flexible circuit board 101 in the compressed state under the cowling 110. The compression force can be great enough to maintain the excess portion 102 of the flexible circuit board 101 in the compressed state under the cowling 110 without damaging the excess portion 102 of the flexible circuit board 101.

The cowling 110 can be detached from the flexible circuit board 101. Detaching the cowling 110 from the flexible circuit board 101 can remove the compression force applied by the cowling 110 on the excess portion 102 of the flexible circuit board 101. The cowling 110 can be detached from the flexible circuit board 101 to enable the excess portion 102 of the flexible circuit board 101 to transition or stretch out of the compressed state and into a decompressed state.

In embodiments, transitioning the excess portion 102 of the flexible circuit board 101 out of the compressed state and into the decompressed state can generate a space between the cowling 110 and the flexible circuit board 101, such as between the cowling 110 and the first surface 103 of the flexible circuit board 101. The space can provide clearance to remove and/or install one or more components, such as the main logic board 604, from the portable electronic device 600 without removing other components, such as the first battery cell and/or the second battery cell, from the portable electronic device 600.

The battery cans, battery assemblies, and various non-limiting components and embodiments as described herein can be used with various electronic devices. Such electronic devices can be any electronic devices known in the art. For example, the device can be a telephone, such as a mobile phone, and a land-line phone, or any communication device, such as a smart phone, including, for example an iPhone®, and an electronic email sending/receiving device. The battery cans, battery assemblies, and various non-limiting components and embodiments as described herein can be used in conjunction with a display, such as a digital display, a TV monitor, an electronic-book reader, a portable web-browser (e.g., iPad®), watch and a computer monitor. The device can also be an entertainment device, including a portable DVD player, conventional DVD player, Blue-Ray disk player, video game console, music player, such as a portable music player (e.g., iPod®), etc. Devices include control devices, such as those that control the streaming of images, videos, sounds (e.g., Apple TV®), or a remote control for a separate electronic device. The device can be a part of a computer or its accessories, laptop keyboard, laptop track pad, desktop keyboard, mouse, and speaker.

While the present disclosure has been described with reference to various implementations, it will be understood that these implementations are illustrative and that the scope of the disclosure is not limited to them. Many variations, modifications, additions, and improvements are possible. More generally, implementations in accordance with the present disclosure have been described in the context of particular implementations. Functionality may be separated or combined in blocks differently in various embodiments of the disclosure or described with different terminology. These and other variations, modifications, additions, and improvements may fall within the scope of the disclosure as defined in the claims that follow.

What is claimed is:

1. A device comprising:
a flexible circuit board; and
a cowling,
wherein a first end of the cowling is configured to be attached to a first surface of the flexible circuit board to maintain a portion of the flexible circuit board in a compressed state under the cowling, and
wherein the first end of the cowling is configured to be detached from the first surface of the flexible circuit board to enable the portion of the flexible circuit board to transition out of the compressed state and into a decompressed state.

2. The device of claim 1, wherein the portion of the flexible circuit board is in a compressed s-shape loop in the compressed state.

3. The device of claim 1, further comprising:
at least one boss attached to the first surface of the flexible circuit board, wherein the first end of the cowling is configured to be attached to the first surface of the flexible circuit board using the at least one boss.

4. The device of claim 1, further comprising:
a main logic board (MLB) positioned above or below a second surface of the flexible circuit board,
wherein a second end of the cowling is further configured to be attached to the MLB.

5. The device of claim 4, further comprising:
at least one boss attached to a surface of the MLB,
wherein the second end of the cowling is configured to be attached to the MLB using the at least one boss.

6. The device of claim 1, wherein the cowling is a material comprising stainless steel.

7. The device of claim 1, wherein the portion of the flexible circuit board comprises a service loop.

8. The device of claim 1, wherein the flexible circuit board is a material comprising copper.

9. The device of claim 1, wherein the cowling is a T-shape.

10. The device of claim 1, wherein the cowling is an L-shape.

11. A cowling comprising:
a first end configured to be attached to a first surface of a flexible circuit board to maintain a portion of the flexible circuit board of the flexible circuit board in a compressed state under the cowling, and
wherein the first end of the cowling is configured to detach from the first surface of the flexible circuit board to enable the portion of the flexible circuit board to transition out of the compressed state into a decompressed state.

12. The cowling of claim 11, wherein the portion of the flexible circuit board is in a compressed s-shape loop in the compressed state.

13. The cowling of claim 11, wherein at least one boss is attached to the first surface of the flexible circuit board, wherein the first end of the cowling is configured to be attached to the first surface of the flexible circuit board using the at least one boss.

14. The cowling of claim 11, wherein a main logic board (MLB) is positioned above or below a second surface of the flexible circuit board, the cowling further comprising a second end configured to be attached to the MLB.

15. The cowling of claim 14, wherein at least one boss is attached to a surface of the MLB, and wherein the second end of the cowling is configured to be attached to the MLB using the at least one boss.

16. The cowling of claim 11, wherein the cowling is a material comprising stainless steel.

17. The cowling claim 11, wherein the portion of the flexible circuit board comprises a service loop.

18. The cowling of claim 11, wherein the flexible circuit board is a material comprising copper.

19. The cowling of claim 11, wherein the cowling is a T-shape.

20. The cowling of claim 11, wherein the cowling is an L-shape.
